(19) United States
(12) Patent Application Publication
(10) Pub. No.: US 2019/0048129 A1
(43) Pub. Date: Feb. 14, 2019

(54) A POLYMER, COMPOSITION, FORMING SACRIFICIAL LAYER AND METHOD FOR SEMICONDUCTOR DEVICE THEREWITH

(71) Applicant: AZ Electronic Materials (Luxembourg) S.a.r.l., Luxembourg (LU)

(72) Inventors: Shigemasa NAKASUGI, Kakegawa-Shi (JP); Yusuke HAMA, Kakegawa-shi (JP); Kazunori KUROSAWA, Hamamatsu-Shi (JP); Hiroshi YANAGITA, Kakegawa-shi (JP); Go NOYA, Kakegawa-shi (JP)

(21) Appl. No.: 16/077,535

(22) PCT Filed: Jan. 19, 2017
(86) PCT No.: PCT/EP2017/000058

§ 371 Date: Aug. 13, 2018

(30) Foreign Application Priority Data
Feb. 11, 2016 (DE) 16000341.4

(51) Int. Cl. C08G 61/02; G03F 7/09; G03F 7/004; C08G 61/12; C08K 5/00; H01L 21/027

(52) U.S. Cl. CPC C08G 61/02; G03F 7/094; G03F 7/0045; C08G 61/12; C08K 5/0025; H01L 21/0271; C08G 2261/90; C08G 2261/312; C08G 2261/316; C08G 2261/344; C08G 2261/65; C08G 2261/76; C08G 2261/314

(57) ABSTRACT

The present invention relates to a polymer, composition, the forming of a sacrificial layer and a method for producing a semiconductor device comprising a step during which a pattern is made using a photoresist by the photolithography method.

### BACKGROUND OF THE INVENTION

The present invention relates to a polymer, composition, the forming of a sacrificial layer and a method for producing a semiconductor device comprising a step during which a pattern is made using a photoresist by the photolithography method.

### BACKGROUND ART

In manufacturing semiconductor devices, micro-processing by lithography using photoresist has been carried out. The micro-processing is a processing method comprising forming a thin layer of a photoresist on a semiconductor substrate such as silicon wafer or the like, irradiating actinic rays such as UV-rays through a mask pattern on which a pattern for a semiconductor device is depicted, developing it to obtain a photoresist pattern, and etching the substrate using the photoresist pattern as a protective layer, thereby forming a fine concavo-convex structure corresponding to the pattern on the surface of the substrate.

In micro-processing, flat surface substrates are generally used as semiconductor substrate. When forming a photoresist pattern on a surface of a substrate, if the surface of the substrate has low flatness, reflected light from the surface of the substrate is irregularly refracted and it becomes difficult to form patterns with high accuracy.

On the other hand, there are cases requiring formation of a concavo-convex structure on a surface of a substrate. Specifically, a pattern is formed by forming a substrate having a concavo-convex structure on the surface of the substrate using photolithography and the like, further forming a coating layer comprising for example silica on the surface, and further processing the layer by photolithography. In this case, when forming a layer directly on a surface of a substrate having a concavo-convex structure, the concavo-convex structure on the surface of the substrate causes non-uniformity in the coating thickness and the final obtained pattern with low accuracy.

To cope with these problems, when using a surface of a substrate having a concavo-convex structure, a process comprising coating a composition containing an organic polymer on a surface of a substrate and filling the organic polymer in the concave part of the substrate to form a flattening surface has been studied. This layer which fills the concave part of the substrate to flatten the surface is called a sacrificial layer (Patent document 1, 2 and 3).

A synthesis study was done for Acenaphthenequinone polymers, but solubility of them were not controlled or applications for actual semiconductor manufacture processes were not proved (Non patent document 1).

### PRIOR ART DOCUMENTS

### Patent Documents

[Patent document 1] JP2009-275228
[Patent document 2] WO2015/182581
[Patent document 3] JPH06-61138 (A)
[Non patent document 1] “Superacid-Catalyzed Polycondensation of Acenaphthenequinone with Aromatic Hydrocarbons” Zolotukhin et al., Macromolecules (2005), vol. 38, p 6005-6014

### SUMMARY OF THE INVENTION

### Problems to be Solved by the Invention

Inventors found sacrificial layer materials in the prior arts have problems which can be improved like gap filling, solubility, thermal durability or weight loss properties.

The present invention provides a polymer which can be used as a sacrificial layer to flatten a substrate surface even if the substrate has a concavo-convex structure. After a selective omission of the sacrificial layer, air gaps are made to separate substrates, electrical elements and so on in order to be a semiconductor circuit.

Inventors found a new synthesis method to achieve a new specific polymer with a preferable molecular weight. They found a new polymer with good solubility and viscosity. Based on the viscosity value, an approximate molecular weight can be calculated (Kobunshi Ronbunsyu, (1986), vol. 43, No. 2, pp. 71-75).

### Means for Solving the Problems

A polymer of the present invention comprises:

a Unit 1 represented by below formula (1)
wherein the weight average molecular weight (Mw) of the polymer satisfies below formula (2),

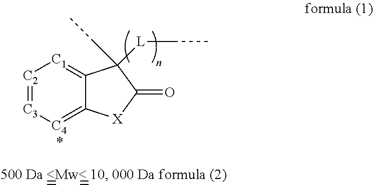

X is a structure represented by below formula (3), (4) or (5),

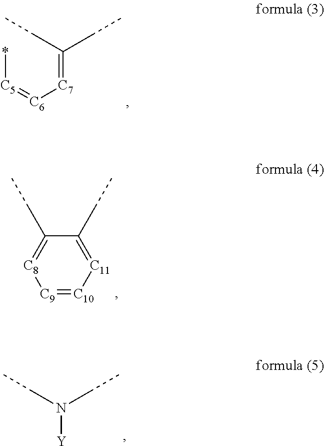

C₁, C₂, C₃, C₄, C₅, C₆, C₇, C₈, C₉, C₁₀ and C₁₁ are carbons, C₅ and C₄ bonds to form aromatic hydro carbon ring at the * position, C₁ and C₂, C₂ and C₃, C₃ and C₄, C₅ and C₆, C₆ and C₇, C₈ and C₉, C₉ and C₁₀, C₁₀ or C₁₁ optionally have one more further aromatic hydro carbon rings or one or more further aliphatic hydrocarbon rings, optionally those rings can be connected, optionally those aromatic hydro carbon rings or aliphatic hydrocarbon rings can be independently substituted by one or more substituents, or unsubstituted,
L is an aromatic hydro carbon rings whose carbon number are on or more than 6 to on or less than 18, —O— or a ketone,
n is an integer selected from 1, 2, 3, 4 or 5,
plural L can be identical to or different from each other,
Y is an aromatic hydro carbon ring whose carbon number is on or more than 6 to on or less than 18, an alkyl whose carbon number is on or more than 1 to on or less than 5 or a hydrogen, and
optionally Y, L, C₁, C₂, C₃, C₄, C₅, C₆, C₇, C₈, C₉, C₁₀ and C₁₁ can be independently substituted by one or more substituents, or unsubstituted.

And a composition of the present invention comprises above polymer and a solvent.

And a sacrificial layer of the present invention comprises above polymer.

And a method of the present invention is an omitting above sacrificial layer comprising at least one step selected from a dissolving, a plasma treatment, an irradiation of high energy radiation or a thermal decomposition.

And a semiconductor device manufacturing method of the present invention comprises:

coating the above composition on a processed substrate,
making the composition to be a sacrificial layer, and
omitting the sacrificial layer with at least one step selected from a dissolving, a plasma treatment, an irradiation of high energy radiation or a thermal decomposition.

And a polymer manufacturing method of the present invention comprises:

(i) mixing molecule A represented by the formula (1)′, molecule B represented by the formula (2)′, a super acid catalyst and solvent A

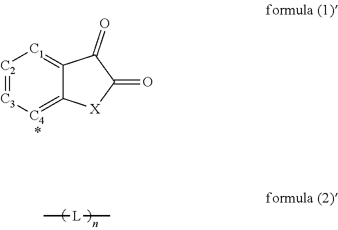

X is a structure represented by below formula (3)′, formula (4)′ or formula (5)′,

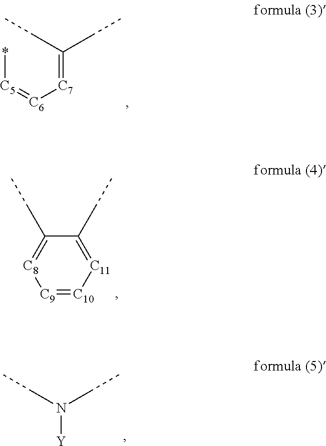

C₁, C₂, C₃, C₄, C₅, C₅, C₇, C₅, C₅, C₁₀ and C₁₁ are carbons, C₅ and C₄ bonds to form aromatic hydro carbon ring at the * position,
C₁ and C₂, C₂ and C₃, C₃ and C₄, C₅ and C₆, C₆ and C₇, C₈ and C₉, C₉ and C₁₀, C₁₀ or C₁₁ optionally have one more further aromatic hydro carbon rings or one or more further aliphatic hydrocarbon rings, optionally those rings can be connected, optionally those aromatic hydro carbon rings or aliphatic hydrocarbon rings can be independently substituted by one or more substituents, or unsubstituted,
L is an aromatic hydro carbon rings whose carbon number are on or more than 6 to on or less than 18, —O— or a ketone,
n is an integer selected from 1, 2, 3, 4 or 5, plural L can be identical to or different from each other,
Y is an aromatic hydro carbon ring whose carbon number is on or more than 6 to on or less than 18, an alkyl whose carbon number is on or more than 1 to on or less than 5 or a hydrogen, and
optionally Y, L, C₁, C₂, C₃, C₄, C₅, C₆, C₇, C₈, C₉, C₁₀ and C₁₁ can be independently substituted by one or more substituents, or unsubstituted,
(ii) the pKa of above (i) mixture is on or more than 0.5, and on or less than 5.0, and
(iii) the polymerization solvent is selected from cyclic ester, cyclic amide, cyclic ketone or mixture of thereof.

### Effects of the Invention

The present invention provides a polymer and a composition comprising thereof, which has excellent solubility and coating properties and can form a sacrificial layer, generating little void inside it, and excellent heat resistance. Further, this composition can achieve high flatness, specifically a height difference on a surface of a sacrificial layer of 10 nm or less, and high surface smoothness, even if it forms a sacrificial layer on a substrate having a concavo-convex structure. Further, the sacrificial layer forming method of the present invention can be combined with flattening treatment by solvent etch back, and thus a reduced roughness of the surface can be achieved.

The present invention provides a polymer manufacturing method, whose process and yield are appropriate for an actual manufacturing. The produced polymer's properties are good as described above.

### DETAILED DESCRIPTION OF THE INVENTION

### Mode for Carrying Out the Invention

Embodiments of the present invention are described below in detail. Those embodiments don't limit the scope of the claimed invention.

<Polymer>

A polymer of the present invention comprises:

a Unit 1 represented by below formula (1),
wherein the weight average molecular weight (Mw) of the polymer satisfies below formula (2),

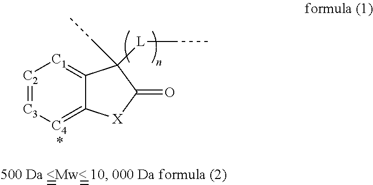

X is a structure represented by below formula (3), (4) or (5),

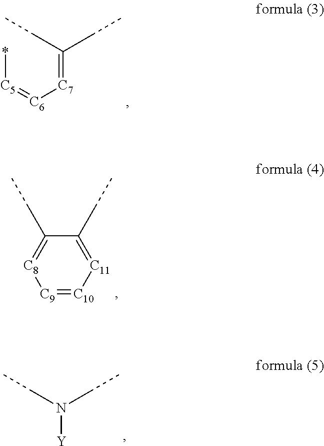

C₁, C₂, C₃, C₄, C₅, C₆, C₇, C₈, C₉, C₁₀ and C₁₁ are carbons, C₅ and C₄ bonds to form aromatic hydro carbon ring at the * position,
C₁ and C₂, C₂ and C₃, C₃ and C₄, C₅ and C₆, C₆ and C₇, C₈ and C₉, C₉ and C₁₀, C₁₀ or C₁₁ optionally have one more further aromatic hydro carbon rings or one or more further aliphatic hydrocarbon rings, optionally those rings can be connected, optionally those aromatic hydro carbon rings or aliphatic hydrocarbon rings can be independently substituted by one or more substituents, or unsubstituted,
L is an aromatic hydro carbon rings whose carbon number are on or more than 6 to on or less than 18, —O— or a ketone,
n is an integer selected from 1, 2, 3, 4 or 5, plural L can be identical to or different from each other,
Y is an aromatic hydro carbon ring whose carbon number is on or more than 6 to on or less than 18, an alkyl whose carbon number is on or more than 1 to on or less than 5 or a hydrogen, and
optionally Y, L, C₁, C₂, C₃, C₄, C₅, C₆, C₇, C₈, C₉, C₁₀ and C₁₁ can be independently substituted by one or more substituents, or unsubstituted.

When X is a structure represented by formula (3), C₄ and C₅ bonds at the * position, and C₁ through C₇ make a naphtyl portion of the Unit 1, for example formula (6). One embodiment of C₁ and C₂ having a phenyl ring as an aromatic hydro carbon ring is formula (6-2).

When L is an aromatic hydro carbon ring, examples of L are phenyl, naphtyl, phenanthrenyl, anthracenyl, pyrenyl, triphenylenyl and fluoranthenyl. More preferable examples of L are a phenyl, —O— and —C(═O)—. Independently plural L can be identical to or different from each other.

When Y is an aromatic hydro carbon ring, examples of Y are each independently phenyl, biphenyl, terphenyl, naphtyl, phenanthrenyl, anthracenyl, pyrenyl, triphenylenyl and fluoranthenyl. When Y is an alkyl, it can be linear or branched. Examples of Y are each independently methyl, ethyl, isopropyl or t-butyl. Preferably, Y is a phenyl, terphenyl, naphtyl, methyl or hydrogen. More preferably Y is a phenyl or hydrogen.

n is an integer selected from 1, 2, 3, 4 or 5. Preferably n is an integer selected from 2, 3, 4 or 5.

Examples of a substituent are alkyl, cyclic alkyl, aromatic hydro carbon ring, alkoxy, nitro, amide, dialkylamino, sulfonamide, imide, carboxyl, sulfonic acid ester, alkylamino, arylamino, ester, oxygen, sulfone and carbonyl.

Preferably Y, L, C₁, C₂, C₃, C₄, C₅, C₆, C₇, C₈, C₉, C₁₀ and C₁₁ are independently unsubstituted, or substituted by methyl, ethyl, t-butyl or hydroxyl. More preferably Y, L, C₁, C₂, C₃, C₄, C₅, C₆, C₇, C₈, C₉, C₁₀ and C₁₁ are unsubstituted.

The Unit 1 in the polymer can be called a repeating Unit. The Unit 1 preferably forms the main chain.

The number of Unit 1 in one invention polymer is preferably between on or more than 2 and on or less than 10, more preferably between on or more than 3 and on or less than 8. In one invention polymer, each Unit 1 can be identical to or different each other, preferably be identical to each other.

m is the number of aromatic hydro carbon rings in one Unit 1. m is preferably between on or more than 2 and on or less than 8.

For example, in the below polymer, there are 5 Unit 1s. And m is 4.

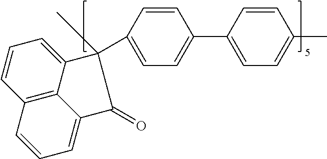

Preferable examples of the formula (1) are represented by formula (6), (7) or (8). Definitions of Y, L, n, C₁, C₂, C₃, C₄, C₅, C₆, C₇, C₈, C₉, C₁₀ and C₁₁ are independently same to described above.

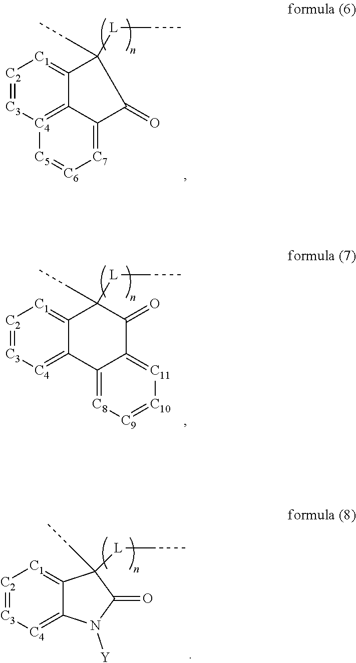

More preferable examples of the formula (1) are represented by formula (6-1) to (8-9). Definitions of Y, L and n are independently same to described above.

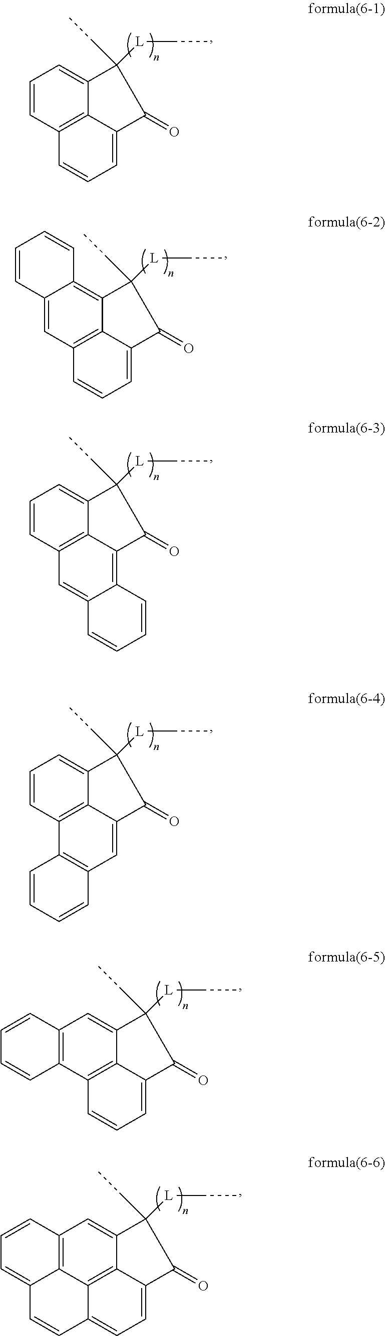

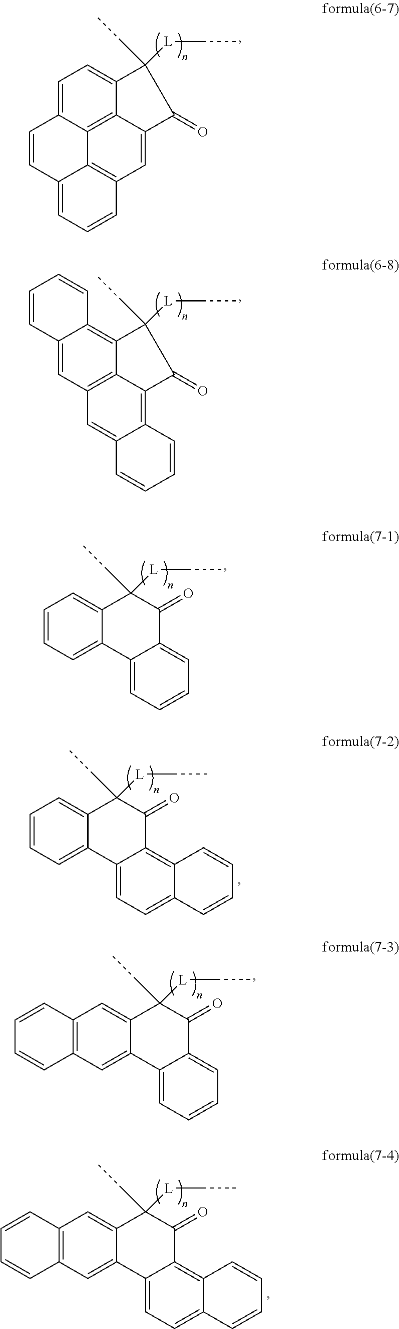

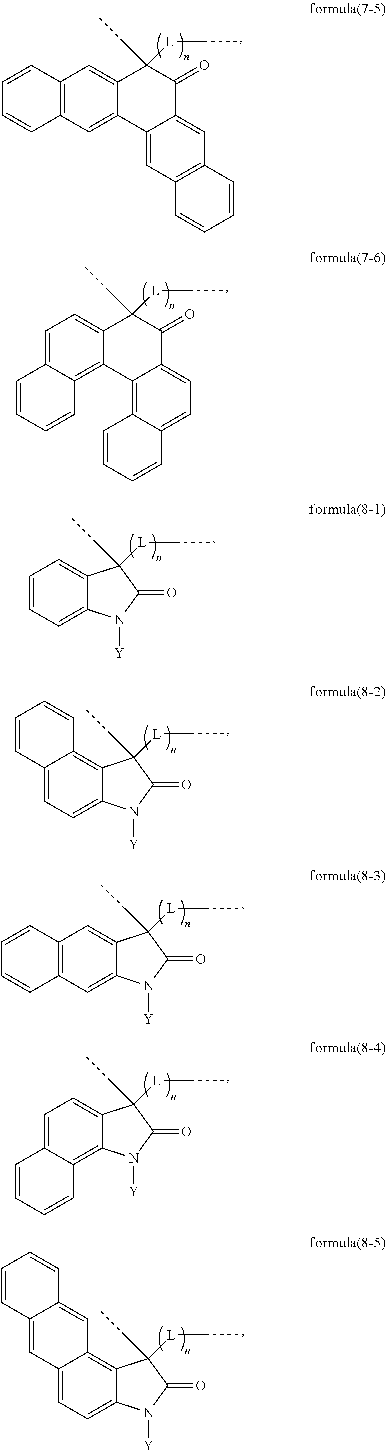

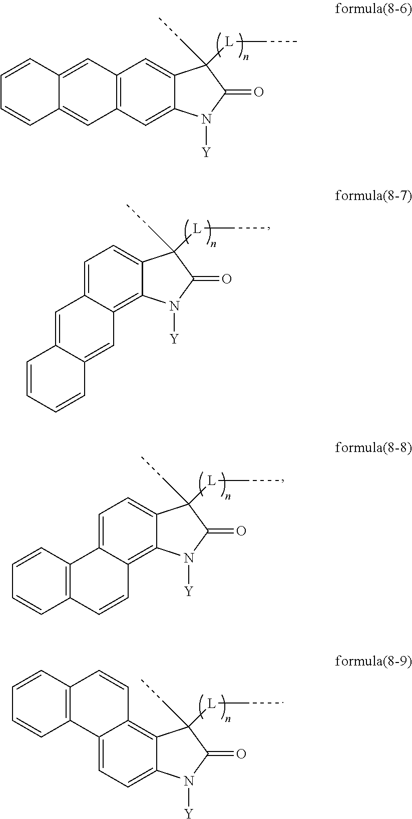

In the above examples, formula (6-1), (7-1) and (8-1) are preferable.

The polymer of this invention can comprise one or more other units in addition to the Unit 1. It is possible for Unit 1 and other units to be connected to randomly, or in order, or in form of a block. The polymer comprises the Unit 1, preferably 40 mol % or more, more preferably 75 mol % or more, based on the total number of repeating units.

Measurement of mass-average molecular weight (Mn) and weight average molecular weight (Mw)

In this specification, Mn and Mw are determined by a gel permeation chromatography (GPC) using GPC columns and under analysis conditions involving a flow rate of 0.6 mL/min, an elution solvent of tetrahydrofuran and a column temperature of 40 Celsius degree using mono-dispersed polystyrene as a standard.

The molecular weight of the polymer used for the present invention can be freely adjusted according to a purpose. The mass-average molecular weight (Mw) preferably satisfy 500 Da≤Mw≤10,000 Da, more preferably 700 Da≤Mw≤7,000 Da, and more preferably 1,000 Da≤Mw≤5,000 Da.

Further, the molecular weight distribution is preferably small from the view point of permeability at coating a composition and coating uniformity.

The sp² hybridized orbital extent of the ketone bonding and the aromatic hydro carbon (C₁ to C₄ benzene) of the Unit 1 is assumed to a cause sustaining a high bonding energy in the Unit 1. The above analysis or assumption doesn't limit the scope of the claimed invention.

<Composition, Sacrificial Layer>

The composition of the present invention comprises the above polymer as a solute, and a solvent. Based on the specific structure and properties described above, the composition can be used for various kinds of purposes. One example of an application of the invention is used for a sacrificial layer.

A sacrificial layer is used for making an airgap (it can be said as a void or a vacancy) between substrate metal wirings (for example electrodes), or protect or sustain an airgap which already exists. A sacrificial layer has properties like filling an airgap, being stable under a certain temperature, and being easy to be omitted in the following step.

With the sacrificial layer of the invention, few voids generated in the process of forming it and high flatness can be achieved because treatment at higher temperature can be performed by high heat resistance of the polymer. And viscosity of the composition can controlled by the polymer contents and the temperature.

The high flatness of the surface correlates to a low roughness. Characterisation of the roughness can be done by visual analysis of Scanning Electron Microscope (SEM) pictures. The visual analysis is either done by somebody highly experienced in these analysis or based on the comparison of the surface to be characterised and a state of the art surface. In the later case, the flatness/roughness is described relative to the reference.

The composition of the present invention comprises a solvent. Such a solvent can be freely selected as long as it can dissolve said polymer. The examples of these solvents include ethyleneglycol monomethyl ether, ethyleneglycol monoethyl ether, methyl cellosolve acetate, ethyl cellosolve acetate, diethyleneglycol monomethyl ether, diethyleneglycol monoethyl ether, propylene glycol, propyleneglycol monomethyl ether (can be called PGME hereinafter), propyleneglycol monomethyl ether acetate (can be called PGMEA hereinafter), propylene glycol propyl ether acetate, toluene, methoxy toluene, anisole, xylene, chlorobenzene, dichlorobenzene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methyl butyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylfolmamide, N,N-dimethylacetamide, n-methyl pyrrolidone, acetonitrile, α-acetolactone, β-propiolactone, γ-butyrolactone, γ-valerolactone, β-lactam, γ-lactam, δ-lactam, γ-butyrolactone and mixture of thereof. A solvent whose molecule has a cyclic structure is preferable, for example cyclic keton, cyclic amide and cyclic ester solvents are preferable. For example cyclohexanone, cyclopentanone, γ-butyrolactone and mixture of thereof are more preferable, cyclohexanone is further preferable.

These solvents can be used alone or in combination of two or more. Further, a high boiling point solvent such as propylene glycol monobutyl ether, propylene glycol monobutyl etheracetate can be added to the solvent.

The composition of the present invention can comprise other components, if necessary. Examples of these components include a cross-linking agent, an acid generator, a surfactant and a leveler compound. These components should be used unless it impairs the effect of the present invention.

The composition of the present invention can comprise a cross-linking agent. The cross-linking agent can be used to prevent the sacrificial layer from mixing with the upper layer. Examples of these cross-linking agents include hexamethylmelamine, hexxamethoxymethylmelamine, 1,2-dihydroxy-N,N′-methoxymethylsuccinimide, 1,2-dimethoxy-N,N′-methoxymethylsuccinimide, 1,3,4,6-tetrakis(methoxymethyl)glycoluril, 4,5-dimethoxy-1,3-bis(methoxyethyl)imidazolidine-2-on, 1,1,3,3,-tetramethoxyurea, tetramethoxymethylglycoluril and N,N′-methoxymethylurea.

The composition of the present invention can comprise an acid generator. The acid generator can be used to accelerate the crosslinking of the forming sacrificial layer.

The acid generators can be classified into thermal acid generators and photo acid generators. These acid generators can be selected among conventionally known ones.

The examples of thermal acid generators which can be used for the composition for forming the sacrificial layer of the present invention include salt and ester which can generate organic acid such as various kinds of aliphatic sulfonic and a salt thereof, various kinds of aliphatic carboxylic acid such as citric acid, acetic acid and maleic acid and a salt thereof, various kinds of aromatic carboxylic acid such as benzoic acid and phthalic acid and a salt thereof, aromatic sulfonic acid and a ammonium salt thereof, various kinds of amine salt, aromatic diazonium salt, and phosphonic acid and a salt thereof. Among the thermal acid generators used in the present invention, a salt consisting of organic acid and organic base is preferable and a salt consisting of sulfonic acid and organic base is more preferable.

The examples of preferable thermal acid generators containing sulfonic acid include p-toluenesulfonic acid, benzene sulfonic acid, p-dodecylbenzenesulfonic acid, 1,4-naphthalenedisulfonic acid and methanesulfonic acid. These acid generators can also be used in combination of two or more.

The examples of the photo acid generator which can be used for the composition of the present invention include onium salt compounds, crosslinkable onium salt compounds, sulfone maleimide derivatives and disulfonyl diazomethane compounds.

The examples of the onium salt compounds include iodnium salt compounds such as diphenyl iodonium hexafluorophosphate, diphenyl iodonium trifluoromethane sulfonate, diphenyl iodonium nonafluoro-noramlbutane sulfonate, diphenyl iodonium perfluoro-normaloctane sulfonate, diphenyl iodonium camphor sulfonate, bis(4-tert-butylphenyl)iodnium camphor sulfonate and bis(4-tert-butylphenyl)iodnium trifluoromethane sulfonate, sulfonium salt compounds such as triphenylsulfonium hexafluoroantimonate, triphenylsulfonium nonafluoro-noramlbutane sulfonate, triphenylsulfonium camphor sulfonate and triphenylsulfonium trifluoromethane sulfonate, and crosslinkable onium salt compounds such as
bis(4-hydroxyphenyl)(phenyl)sulfonium trifluoromethane sulfonate,
bis(4-hydroxyphenyl)(phenyl)sulfonium-1,1,2,2,3,3,4,4,4-nonafluorobutane-1-sulfonate, phenyl
bis(4-(2-(vynyloxy)ethoxy)phenyl)sulfonium-1,1,2,2,3,3,4,4-octafluorobutane-1,4-disulfonate,
tris(4-(2-(vynyloxy)ethoxy)phenyl)sulfonium-1,1,2,2,3,3,4,4-octafluorobutane-1,4-disulfonate, but not limited to them.

The examples of the sulfone maleimide derivative include N-(trifluoromethane sulfonyloxy)succinimide, N-(nonafluoro-noramlbutane sulfonyloxy)succinimide, N-(camphor sulfonyloxy)succinimide and N-(trifluoromethane sulfonyloxy)naphtalimide.

The examples of the disulfonyl diazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane and methylsulfonyl-p-toluenesulfonyldiazomethane. In the composition of the present invention, these photo acid generators can also be used in combination of two or more.

The composition of the present invention is provided by mixing said components and dissolving them uniformly. The blended ratio of each component is not limited but properly adjusted according to a purpose.

The content ratio of the invention polymer in the invented composition is preferably 0.2 to 25 parts mass, more preferably 1 to 20 parts mass, further preferably 5 to 15 parts mass, based on 100 parts mass of the total mass of the composition.

Without specific definition, the term of “part” is used as mass basis in hereafter.

Further, when the composition of the present invention comprises the cross-linking agent, the content ratio of the cross-linking agent is preferably 5 to 40 parts mass, more preferably 10 to 30 parts mass based on 100 parts mass of the total of the polymer.

Further, when the composition of the present invention comprises an acid generator, the content ratio of the acid generator is preferably 0.01 to 20 parts mass, more preferably 0.02 to 5 parts mass, based on 100 parts mass of the polymer. The shape of photoresist can be controlled by adding the acid generator. It is not completely explained but it is assumed that acidity of the sacrificial layer is controlled by adding the acid generator. In other words, a more suitable rectangular shape of photoresist patterns can be formed by adding the acid generator.

The composition of the present invention is preferably used after filtration with pore diameter of about 0.2 to 0.05 μm. The composition prepared thus is excellent in storage stability at a room temperature for a long time.

<A Method for Forming a Sacrificial Layer, a Pattern Formation Method>

The method for forming sacrificial layer and pattern formation method of the present invention are as follows.

The composition for forming a sacrificial layer of the present invention is coated on a semiconductor substrate, such as a silicon/silicon dioxide substrate, a silicon nitride substrate, a silicon wafer substrate, a glass substrate and an ITO substrate, by an appropriate coating method such as a spinner and a coater.

Here, a substrate having a conocavo-convex structure formed on a surface can be used.

According to necessity, the coated layer on the substrate can be dried to remove part of the solvent contained in the coated layer. The drying treatment is carried out at a low temperature, preferably below 200° C., to remove the solvent. It is assumed that during the drying treatment, a cross-linking reaction does practically not proceed in the coated layer.

Then, the coated layer is pre-baked in an inert atmosphere, if necessary. This coated layer after pre-baked can be called pre-baked layer for convenience. This pre-baking process further improves flatness of the formed coated layer. Such pre-baking is carried out by heating in an inert atmosphere (preferably in nitrogen gas). Heating temperature is generally 200 to 550° C., preferably 300 to 550° C., and the pre-baking time is generally 0.3 to 120 minutes, preferably 1 to 60 minutes.

In the coated layer after pre-baking, polymers are unreacted as mentioned above. Thus, the surface of the coated layer can be dissolved and removed by bringing the surface of the coated layer into contact with a solvent which can dissolve the polymers. This process is called solvent etch back. According to the present invention, further flatness of the surface can be achieved by applying solvent etch back to the coated layer before cross-linking reaction

The processing conditions of this surface layer removing step are not limited and kinds of solvent, method for contacting the surface of the coated layer with the solvent, and contacting time can be selected arbitrarily as needed. However, the solvent is generally selected same solvent as used in the composition for a sacrificial layer. The contacting method is preferably dipping the coated layer into the solvent because this method is simple. The contacting time is generally 1 to 10 minutes, preferably 1 to 5 minutes.

The maximum thickness of the coated layer can be reduced to, for example about ⅓ by this surface removing step. Here, the maximum thickness of the coated layer means the maximum length from the surface of the substrate to the surface of the coated layer. When the substrate has a concavo-convex structure, it means the distance from the bottom of the concave part to the surface of the coated layer. Generally, the surface is removed not to expose the surface of the substrate from the coated layer. Specifically, when there are grooves of 100 nm depth formed and coated layer of maximum thickness of 300 nm on it, removed surface layer is generally less than 200 nm.

Then, the sacrificial layer is formed by further baking the coated layer in the presence of oxygen. Regarding the baking condition, the baking temperature is generally 200 to 550° C., preferably 300 to 550° C., baking time is generally 0.3 to 120 minutes, preferably 1 to 60 minutes. When pre-baking is carried out before baking, the baking time can be reduced. This baking promotes the cross-linking reaction in the sacrificial layer to form the sacrificial layer.

With baking or reducing atmosphere pressure, the invention composition can be made to be a sacrificial layer.

In this sacrificial layer formation, a substrate having a concavo-convex structure on a surface can be used as a substrate. The concavo-convex structure on the surface of the substrate may be formed in an optional manner, for example photolithography. The formed shape of the concave part can be arbitrary shape such as hole and groove. The cross sectional shape of the concave part is also arbitrary and can be square, trapezoid or semicircular. When the substrate having concave part on the surface of the substrate, typically groove-like concave part, of which cross sectional shape is square, is formed. In this case, the width of the groove is generally 1 to 1,000 nm, preferably 40 to 60 nm, the depth of the groove is generally 20 to 1,000 nm, preferably 80 to 300 nm. Various width and depth of the groove may be mixed. On the other hand, the substrate can have columnar or wall-like convex part, for example fin. Then, when the composition for forming a sacrificial layer of the present invention is applied to a substrate having different size of concave parts and convex parts, higher flatness sacrificial layer can be formed than the sacrificial layer formed by using conventional composition. Though difference in height on the surface of the substrate was generally several ten nm in the conventional sacrificial layer formation method, the flatness is improved by sacrificial layer formation method of the present invention using the same substrate. Especially, difference in height is reduced to 10 nm or less if mixed with the pre-baking step, and it can be reduced to 5 nm or less if further mixed with the surface layer removing step. Here, “difference in height” means the difference between the height of the vertex of highest convex part (highest point) and the height of the bottom of lowest concave part (lowest point). This difference in height can be measured by, for example, an optical interference type film thickness measuring apparatus or an electron scanning microscope. Specifically, film thicknesses of randomly selected points are measured by an electron scanning microscope, and the difference between the thickest point and the thinnest point among them can be regarded as the difference in height.

For example a positive type photoresist composition is coated on the sacrificial layer formed in this way. Here, the positive type photoresist reacts by light irradiation and has solubility with respect to developing solution increased by the reaction. Photoresist used for the present invention is limited but include positive-type photoresist which has photosensitivity with the light for patterning, negative-type photoresist, and negative-tone-development (NTD) photoresist.

Then, the photoresist layer is subjected to exposure through predetermined mask. The wavelength used for the exposure is not limited, but wavelength 13.5 to 248 nm is preferable for the exposure. Specifically, a KrF excimer laser (wavelength 248 nm), an ArF excimer laser (wavelength 193 nm) and an extreme urtraviolet light (wavelength 13.5 nm) can be used and an ArF excimer laser is preferably used.

After the exposure, post exposure bake (PEB) can be carried out, if necessary. The temperature of post exposure bake is generally 80° C. to 150° C., preferably 100° C. to 140° C., and baking time is generally 0.3 to 5 minutes, preferably 0.5 to 2 minutes.

Then, development carried out with a developing solution. By the development, exposure d positive type photoresist layer is removed to form a resist pattern.

The examples of the developing solution used for above pattern formation method include alkaline aqueous solution which include aqueous solution of alkali metal hydroxide such as potassium hydroxide and sodium hydroxide, aqueous solution of quaternary ammonium hydroxide such as tetramethylammonium hydroxide, tetraethylammonium hydroxide, choline and amine aqueous solution such as ethanolamine, propylamine, ethylenediamine. Particularly, 2.38 weight % TMAH aqueous solution can be used. Sacrificial layer can be dissolved and removed easily by using such developing solution at room temperature. Further, the developing solution can be added for example a surfactant.

The temperature of the developing solution is generally 5° C. to 50° C., preferably 20 to 40° C., and developing time is generally 10 to 300 seconds, preferably 30 to 60 seconds.

One aspect of the polymer of this invention is that the main chain (Unit 1) comprises aromatic hydro carbons. Preferably the polymer exhibits high thermal durability, for example around 400 Celsius degree. It would suitable for a sacrificial layer in the view point of semiconductor manufacturing process as hereinbefore.

After the semiconductor manufacturing process advanced, the polymer of this invention can be selectively omitted, for example by a plasma treatment.

One embodiment of the sacrificial layer of this invention is coating a processed substrate with concavo-convex structure. With a sacrificial layer coating, the surface of them are flattened. For example, photoresist can be coated and developed on the sacrificial layer. The sacrificial layer can support and sustain the photoresist on it and trench. And the sacrificial layer can protect them against physical or chemical damage. After an etching or a plasma treatment, metal wiring can be formed with a chemical vapor deposition. Those conditions can be adjusted not to decompose the sacrificial layer. And the sacrificial layer can be selectively omitted in the following step. Measures to omit it are not restricted, but for example dissolving, plasma treatment, irradiation of high energy radiation, thermal decomposition can be used. Preferably the sacrificial layer can be treated by plasma, more preferably dry etching and wet etching.

The sacrificial layer of this invention having good coating and penetration properties are preferable in the view point of a semiconductor process.

It is preferable that the invention sacrificial layer is not decomposed at a temperature which decomposes a photoresist. For example, the sacrificial layer is not substantially decomposed at 450 Celsius degree. But the sacrificial layer can be substantially decomposed at 600 Celsius degree. In particular the weight loss is on or less than 2% is preferable of the sacrificial layer after 10 hours heating at 450 Celsius degree, on or less than 1% is more preferable. And the weight loss is on or more than 80% is preferable of the sacrificial layer after 1 hour heating at 600 Celsius degree, on or more than 90% is more preferable.

The main solid component of this invention composition is above invention polymer. So, the sacrificial layer is substantially made by the invention polymer. It means the weight loss of the sacrificial layer and the polymer are substantially identical.

Since high temperatures during the decomposition could damage other layers or structures on the processed substrate. So, omitting the invention sacrificial layer with dissolving, a plasma treatment or an irradiation of high energy radiation are more preferable.

Because the composition as a sacrificial layer has to penetrate into a narrow trench or a small gap, controlling its viscosity could be useful. After coating the composition on the substrate, higher temperature condition can cause its viscosity lower which means more penetrable. With using this technique, a composition with relatively high viscosity in a room temperature also could penetrate a narrow trench or a small gap sufficiently.

<Polymer Synthesis>

A polymer manufacturing method of the present invention comprises:

(i) mixing molecule A represented by the formula (1)′, molecule B represented by the formula (2)′, a super acid catalyst and solvent A

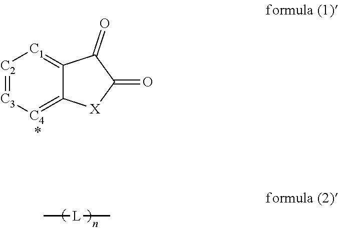

X is a structure represented by below formula (3)′, formula (4)′ or formula (5)′,

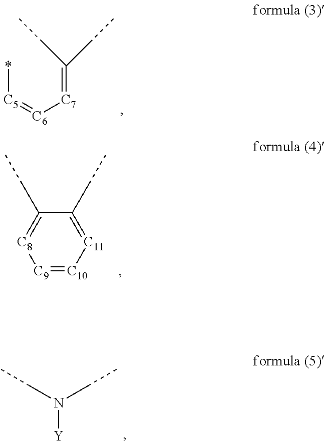

C₁, C₂, C₃, C₄, C₅, C₆, C₇, C₈, C₉, C₁₀ and C₁₁ are carbons, C₅ and C₄ bonds to form aromatic hydro carbon ring at the * position,
C₁ and C₂, C₂ and C₃, C₃ and C₄, C₅ and C₆, C₆ and C₇, C₈ and C₉, C₉ and C₁₀, C₁₀ or C₁₁ optionally have one more further aromatic hydro carbon rings or one or more further aliphatic hydrocarbon rings, optionally those rings can be connected, optionally those aromatic hydro carbon rings or aliphatic hydrocarbon rings can be independently substituted by one or more substituents, or unsubstituted,
L is an aromatic hydro carbon rings whose carbon number are on or more than 6 to on or less than 18, —O— or a ketone,
n is an integer selected from 1, 2, 3, 4 or 5,
plural L can be identical to or different from each other,
Y is an aromatic hydro carbon ring whose carbon number is on or more than 6 to on or less than 18, an alkyl whose carbon number is on or more than 1 to on or less than 5 or a hydrogen, and
optionally Y, L, C₁, C₂, C₃, C₄, C₅, C₅, C₇, C₈, C₅, C₁₀ and C₁₁ can be independently substituted by one or more substituents, or unsubstituted,
(ii) the pKa of above (i) mixture is on or more than 0.5, and on or less than 5.0, and
(iii) the polymerization solvent is selected from cyclic ester, cyclic amide, cyclic ketone or mixture of thereof.

As below scheme, bonding molecule A and molecule B makes Unit 1 represented by formula (1) described above.

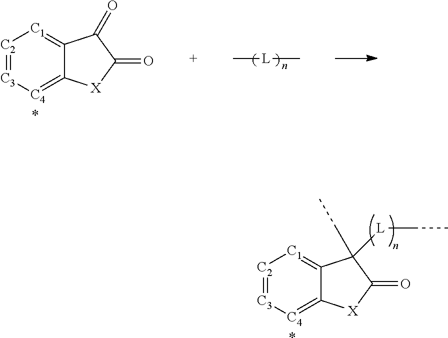

Polymerizing Unit 1 and other unit if exist makes the polymer of the invention described above.

The definitions, explanations and examples of Y, L, n, C₁, C₂, C₃, C₄, C₅, C₆, C₇, C₈, C₉, C₁₀ and C₁₁ in formula (1)′, (2)′ and (3)′ are independently same to each of them in formula (1) and (3) described above.

Preferable examples of formula (1)′ are formula (6)′, (7)′ or (8)′. Definitions of Y, C₁, C₂, C₃, C₄, C₅, C₆, C₇, C₈, C₉, C₁₀ and Gi are independently same to described above.

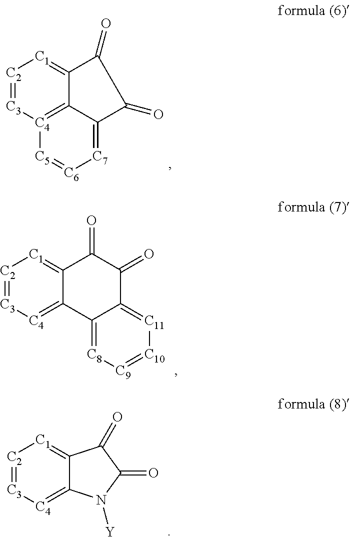

More preferable examples of formula (1)′ are formula (6-1)′ to (8-9)′ described below.

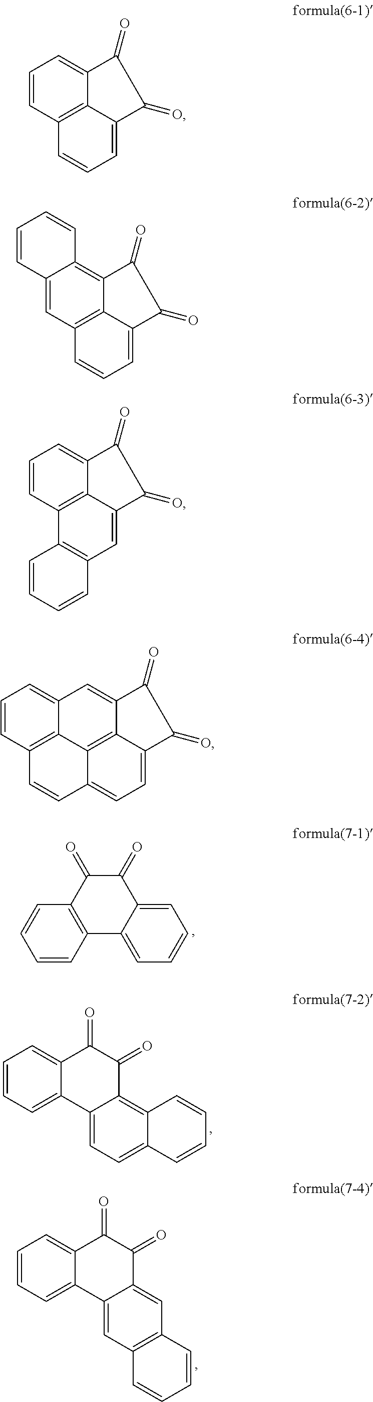

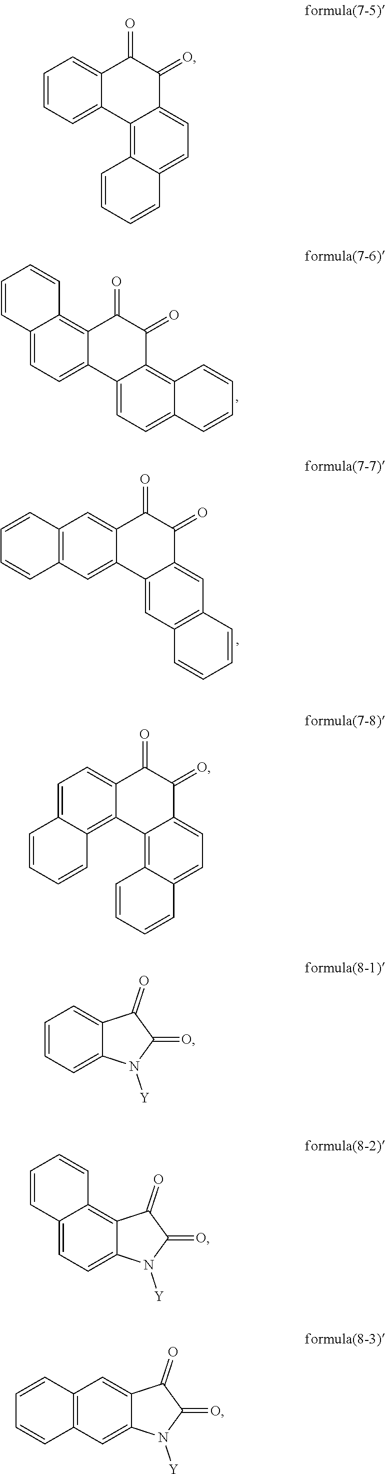

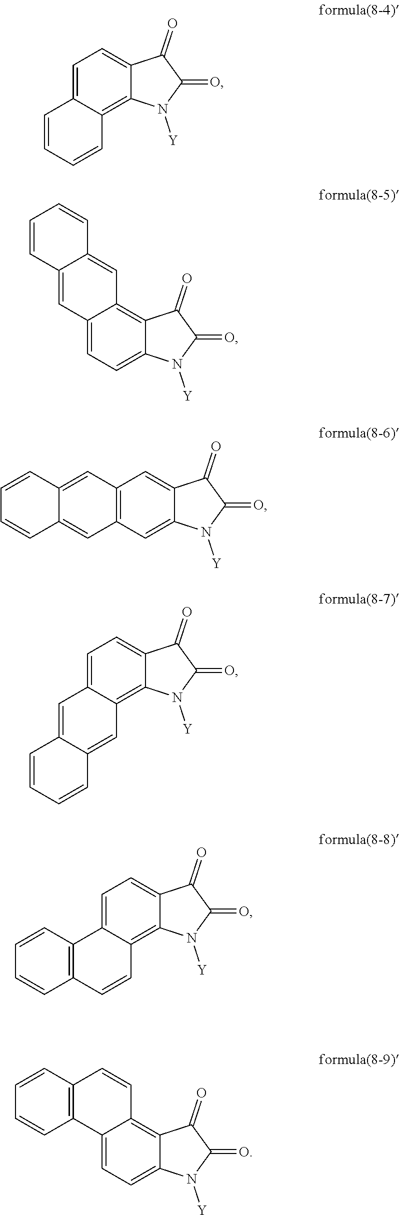

More preferable examples of formula (1′) are (6-1)′, (7-1)′ and (8-1)′.

The super acid catalyst of the present invention is a catalyst preferably has a H₀ (Hammett acidity function) from −26 to −13, more preferably from −20 to −14. Examples of the super acid catalyst of the present invention are Trifluoromethanesulfonic acid (TFSA), perfluoroethanesulfonic acid, perfluorobutanesulfonic acid, perfluorohexanesulfonic acid, fluoroantimonic (v) acid, fluorosulfonic acid and mixture of thereof. More preferable example of the super acid catalyst of the present invention is TFSA.

The solvent A of the present invention is a solvent to dissolve molecule A and molecule B in it, and lower the pKa of (i) mixture. This condition is assumed to make the bonding reaction of molecule A and molecule B more preferably to achieve an appropriate weight average molecular weight. Examples of the solvent A are cyclic ester, cyclic amide, cyclic ketone or mixture of thereof. Preferable examples of the solvent A are α-acetolactone, β-propiolactone, γ-butyrolactone, γ-valerolactone, β-lactam, γ-lactam, δ-lactam, γ-butyrolactone, N-Methyl-2-Pyrrolidone (NMP), cyclohexanone, cyclopentanone and mixture of thereof. Preferable example of the solvent A of the present invention are γ-butyrolactone, γ-valerolactone and NMP.

The pKa (acid dissociation constant) of the (i) mixture can be measured with known and usual way. In this invention method, the pKa is on or more than 0.5 and on or less than 5.0, preferably on or more than 1.0 and on or less than 3.0.

The weight average molecular weight (Mw) of the manufactured polymer by above method can be measured as described above. Preferable Mw of the synthesized polymer can be same to described above.

The temperature of the synthesis condition can be controlled by known and usual way. The temperature is between 80 to 160 Celsius degree, preferably 130 to 150 Celsius degree.

Ratio of each (i) mixture components are molecule A is 1 part mass, molecule B is on or more than 0.5 to on or less than 2.0 parts mass, a super acid catalyst is on or more than 2.0 to on or less than 5.0 parts mass, and solvent A is on or more than 1.0 to on or less than 4.0 parts mass.

Preferably B is on or more than 0.5 to on or less than 1.0 mass. Preferably a super acid catalyst is on or more than 2.5 to on or less than 4.0 mass. Preferably solvent A is on or more than 1.0 to on or less than 2.0 mass.

For example, when “molecule A 100 g, molecule B 100 g, a super acid catalyst 300 g and solvent A 300 g are mixed as the (i) mixture components”, it means “molecule A is 1 part mass, molecule B is 1 part mass, a super acid catalyst is 3 parts mass and a solvent A is 3 parts mass” in it.

The present invention is further explained using the following examples, but embodiments of the present invention are not restricted to these examples. Tests and evaluations were done as described below.

<Molecular Weight>

Mass-average molecular weights (Mn) and weight average molecular weights (Mw) of polymers were measured by a gel permeation chromatography (GPC) using mono-dispersed polystyrene as a standard. Molecular weight distributions (Mw/Mn) were calculated by them.

<Weight Loss>

In the nitrogen gas atmosphere, temperature were gained 20 Celsius degree/min, and the polymers are heated for 10 hours at 450 Celsius degree. The differences of the polymer weights are measured. And weight loss ratio (%) were calculated.

<Gap Filling Property Check>

The ability to gap filling of the polymers are checked with cross section Scanning Electron Microscope (SEM).

### Synthesis Example 1

### Synthesis of Poly Acenaphthenequinone-Biphenyl (Polymer P1)

Polymer synthesis was conducted in three-necked flask equipped with magnetic stirrer and condenser tube. Acenaphthenequinone (molecule A, 50 parts), biphenyl (molecule B, 40 parts), γ-butyrolactone (GBL, 140 parts) were stirred under a dry nitrogen at 140 Celsius degree and Trifluoromethanesulfonic acid (TFSA, 80 parts) was added in this solution slowly.

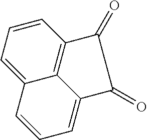 [SMILES: O=C1C(=O)c2cccc3cccc1c23]

Acenaphthenequinone,

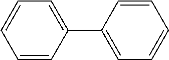 [SMILES: c1ccc(-c2ccccc2)cc1]

biphenyl

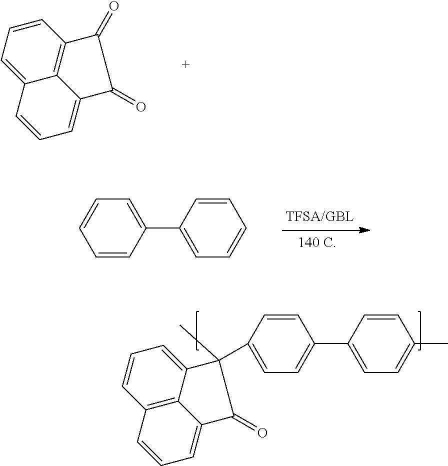

After 8 hours, the solution was poured into methanol (700 parts). The black solid was filtered off, washed copiously with methanol (50 parts), and then extracted with refluxing methanol and finally with methyl-tert-butyl ether, before drying at 120° C. under vacuum. We got the Polymer P1, 68 parts (yield 80%).

Mn and Mw were measured by GPC. Mn was 1,041 Da. Mw was 1655 Da. Molecular weight distributions (Mw/Mn) was 1.59.

### Synthesis Example 2 to 7

Polymers P2 to P7 were synthesized same as the Synthesis example 1 except for Molecule A and Molecule B were changed as described Table 1. Molecular weights of them are measured as the Synthesis example 1.

TABLE 1

| | | | | | | Mw/ | Yield |
|---|---|---|---|---|---|---|---|
| | Polymer | Molecule A | Molecule B | Mn | Mw | Mn | (%) |
| Synt. ex. 1 | P1 | Acenaphthenequinone | Biphenyl | 1041 | 1655 | 1.59 | 80 |
| Synt. ex. 2 | P2 | Acenaphthenequinone | 2,2′ | 2030 | 3979 | 1.96 | 82 |
| | | | Biphenol | | | | |
| Synt. ex. 3 | P3 | Acenaphthenequinone | Diphenylether | 2320 | 4733 | 2.04 | 97 |
| Synt. ex. 4 | P4 | Acenaphthenequinone | 3- | 2210 | 4663 | 2.11 | 91 |
| | | | Methoxybiphenyl | | | | |
| Synt. ex. 5 | P5 | Acenaphthenequinone | 4- | 1319 | 2321 | 1.76 | 72 |
| | | | Phenoxybenzophenone | | | | |
| Synt. ex. 6 | P6 | 1- | Biphenyl | 2678 | 4981 | 1.86 | 92 |
| | | Phenylisatin | | | | | |
| Synt. ex. 7 | P7 | 9,10- | Biphenyl | 987 | 1599 | 1.62 | 63 |
| | | Phenanthrenequinone | | | | | |

“Synt. ex.” means “Synthesis example”.

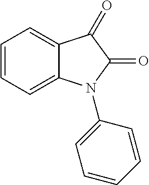 [SMILES: O=C1C(=O)N(c2ccccc2)c2ccccc21]

### 1-Phenylisatin,

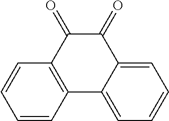 [SMILES: O=C1C(=O)c2ccccc2-c2ccccc21]

### 9,10-Phenanthrenequinone,

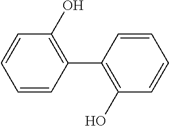 [SMILES: Oc1ccccc1-c1ccccc1O]

### 2,2′ Biphenol,

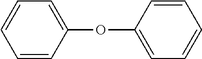 [SMILES: c1ccc(Oc2ccccc2)cc1]

### Diphenylether,

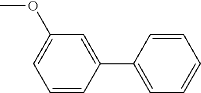

### 3-Methoxybiphenyl,

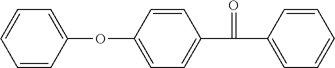 [SMILES: O=C(c1ccccc1)c1ccc(Oc2ccccc2)cc1]

### 4-Phenoxybenzophenone,

### Example 1

A composition was obtained by adding Cyclohexanone (Solvent, 90 parts) into the polymer P1 (10 parts), and stirring them 30 minutes at the room temperature.

As described above, a weight loss ratio (%) was obtained. A silicon wafer was coated by spin coating with the obtained composition. And the silicon wafer was heated for 2 minutes at 350 Celsius degree on a hotplate. Then, the silicon wafer was heated again 2 hours at 500

Celsius degree on a hotplate. The thin polymer layer (.i.e., heated composition) on the silicon wafer was shave off from the wafer, and gathered.

The gathered composition was heated gain 10 hours at 450 Celsius degree in the nitrogen atmosphere, and weight loss ratio (%) was 0%.

As described above, a gap filling property was checked. A SiO₂ wafer with trenches (approximately 10 nm width, 300 nm height) was prepared. The SiO₂ wafer was coated by spin coating with the obtained composition above. And the SiO₂ wafer was heated for 2 minutes at 350 Celsius degree on a hotplate. Then, the SiO₂ wafer was heated again 2 hours at 500 Celsius degree on a hotplate. A cross section of the heated SiO₂ wafer was checked by SEM.

### Example 2 to 7. Comparative Example 1

In the Example 2 to 7, compositions were obtained same as the Example 1 except for components are changed as described Table 2. In the Comparative example 1, the Fullerene C60 (Frontier Carbon Corporation) was used as a polymer.

TABLE 2

| | | | Weight loss | Gap |
|---|---|---|---|---|
| | Polymer | Solvent | ratio (%) | filling |
| Example 1 | P1 | Cyclohexanone | 0 | A*¹ |
| Example 2 | P2 | Cyclohexanone | 0.5 | A |
| Example 3 | P3 | Cyclohexanone | 0.4 | A |
| Example 4 | P4 | Cyclohexanone | 0.8 | A |
| Example 5 | P5 | Cyclohexanone | 0.9 | A |
| Example 6 | P6 | Cyclohexanone | 0 | A |
| Example 7 | P7 | Cyclohexanone | 0 | A |
| Comparative | Fullerene | O-xylene | 0 | B*² |
| example 1 | C60 | | | |

*¹A means that gaps were filled, and void or particle were not found.
*²B means that gaps were filled, but some void and particle were found.

1.-15. (canceled)

16. A polymer comprising a Unit 1 represented by below formula (1),
wherein the weight average molecular weight (Mw) of the polymer satisfies below formula (2), 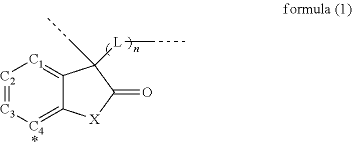
500 Da≤Mw≤10,000 Da formula (2)
X is a structure represented by below formula (3), (4) or (5), 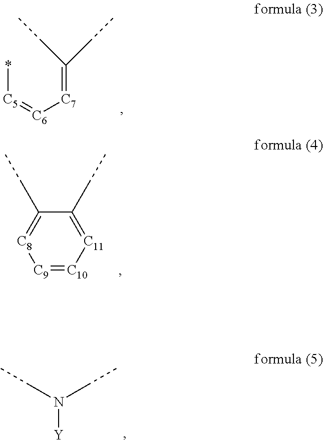
C₁, C₂, C₃, C₄, C₅, C₆, C₇, C₈, C₉, C₁₀ and C₁₁ are carbons, C₅ and C₄ bonds to form aromatic hydro carbon ring at the * position,
C₁ and C₂, C₂ and C₃, C₃ and C₄, C₅ and C₆, C₆ and C₇, C₈ and C₉, C₉ and C₁₀, C₁₀ or C₁₁ optionally have one more further aromatic hydro carbon rings or one or more further aliphatic hydrocarbon rings, optionally those rings can be connected, optionally those aromatic hydro carbon rings or aliphatic hydrocarbon rings can be independently substituted by one or more substituents, or unsubstituted,
L is an aromatic hydro carbon rings whose carbon number are on or more than 6 to on or less than 18, —O— or a ketone,
n is an integer selected from 1, 2, 3, 4 or 5,
plural L can be identical to or different from each other,
Y is an aromatic hydro carbon ring whose carbon number is on or more than 6 to on or less than 18, an alkyl whose carbon number is on or more than 1 to on or less than 5 or a hydrogen, and
optionally Y, L, C₁, C₂, C₃, C₄, C₅, C₆, C₇, C₈, C₉, C₁₀ and C₁₁ can be independently substituted by one or more substituents, or unsubstituted.

17. The polymer according to claim 16, wherein the formula (1) is represented by formula (6), (7) or (8), and
the definitions of Y, L, n, C₁, C₂, C₃, C₄, C₅, C₆, C₇, C₈, C₉, C₁₀ and C₁₁ are independently same to claim 16,

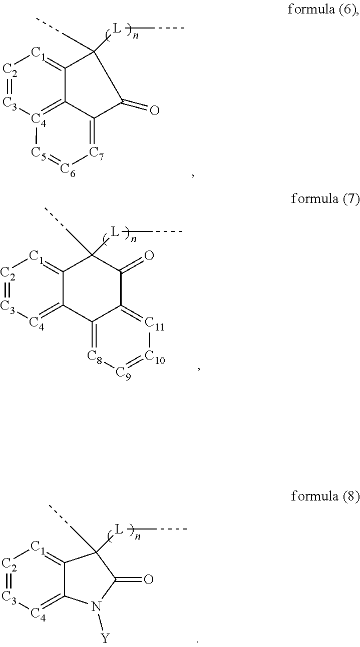

18. The polymer according to claim 16, wherein the formula (1) is represented by at least one selected from formula (6-1) to (8-9),
the definitions of Y, L or n are independently same to claim 16,

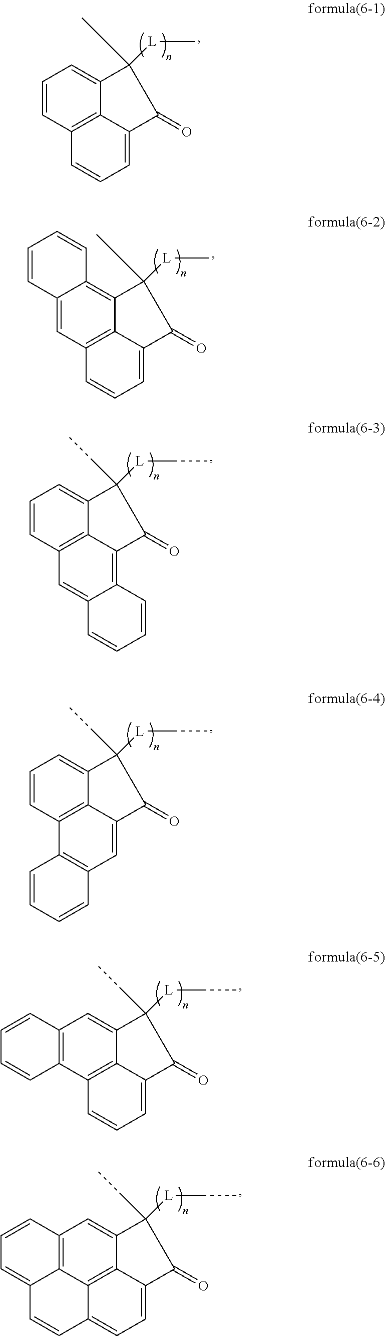

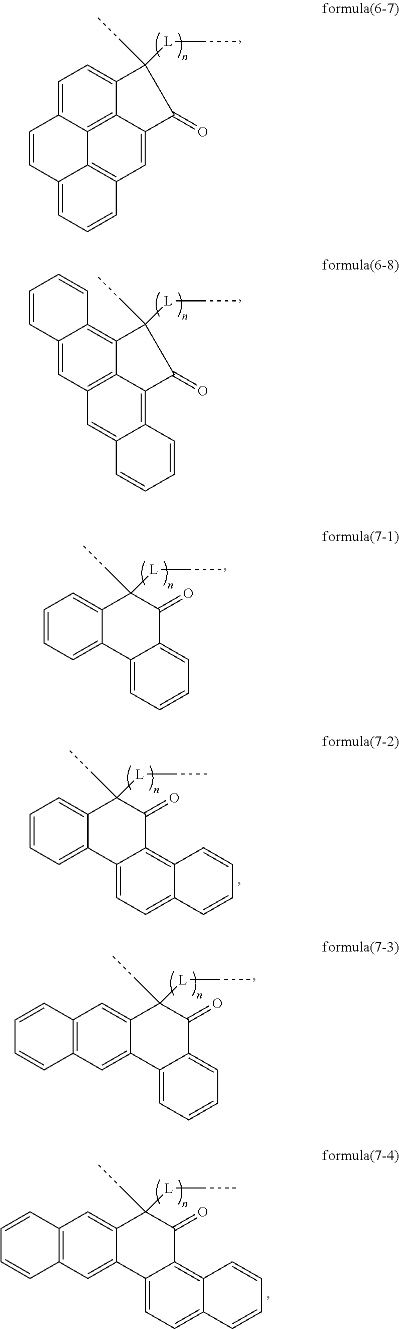

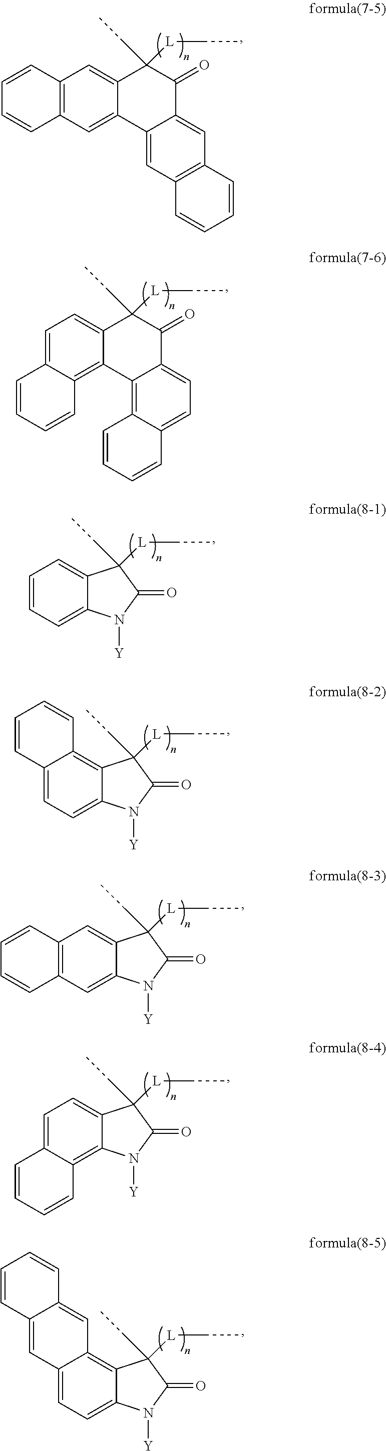

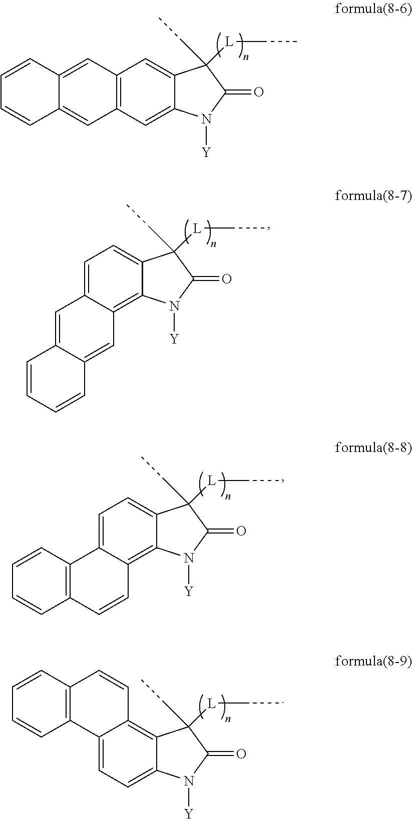

19. The polymer according to claim 16, wherein the L is a phenyl, naphtyl, phenanthrenyl, anthracenyl, pyrenyl, triphenylenyl, fluoranthenyl, —O— or —C(═O)—, and the Y is a phenyl, biphenyl, terphenyl, naphtyl, phenanthrenyl, anthracenyl, pyrenyl, triphenylenyl, fluoranthenyl, methyl, ethyl, isopropyl, t-butyl or hydrogen.

20. A composition comprising the polymer according to claim 16, and a solvent.

21. The composition according to claim 20, which further comprises a cross-linking agent, an acid generator or mixture of thereof.

22. The composition according to claim 20, wherein the composition is used for a sacrificial layer.

23. A sacrificial layer comprising the polymer according to claim 16.

24. A method to omit the sacrificial layer according to claim 23 comprising at least one step selected from a dissolving, a plasma treatment, an irradiation of high energy radiation or a thermal decomposition.

25. A semiconductor device manufacturing method comprising
coating the composition according to claim 20 on a processed substrate,
making the composition to be a sacrificial layer, and in a later step
omitting the sacrificial layer with at least one step selected from dissolving, plasma treatment, irradiation with high energy radiation or thermal decomposition.

26. A semiconductor device manufacturing method according to claim 25, wherein further comprising a step forming another layer on the sacrificial layer before omitting the sacrificial layer.

27. A polymer manufacturing method comprising
(i) mixing molecule A represented by the formula (1)′, molecule B represented by the formula (2)′, a super acid catalyst and solvent A 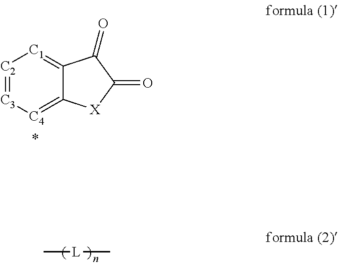
X is a structure represented by below formula (3)′, formula (4)′ or formula (5)′, 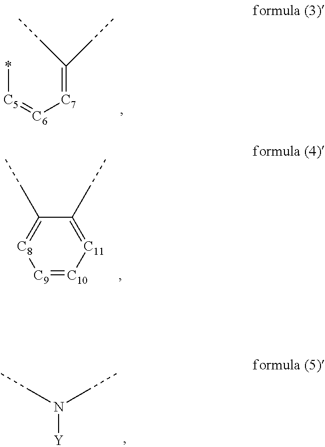
C₁, C₂, C₃, C₄, C₅, C₆, C₇, C₈, C₉, C₁₀ and C₁₁ are carbon, C₅ and C₄ bond to form an aromatic hydro carbon ring at the * position,
C₁ and C₂, C₂ and C₃, C₃ and C₄, C₅ and C₆, C₆ and C₇, C₈ and C₉, C₉ and C₁₀, C₁₀ or C₁₁ optionally have one more further aromatic hydro carbon rings or one or more further aliphatic hydrocarbon rings, optionally those rings can be connected, optionally those aromatic hydro carbon rings or aliphatic hydrocarbon rings can be independently substituted by one or more substituents, or unsubstituted,
L is an aromatic hydro carbon ring whose carbon number is on or more than 6 to on or less than 18, —O— or a ketone,
n is pan integer selected from 1, 2, 3, 4 or 5,
plural L can be identical to or different from each other,
Y is an aromatic hydro carbon ring whose carbon number is on or more than 6 to on or less than 18, an alkyl whose carbon number is on or more than 1 to on or less than 5 or a hydrogen, and
optionally Y, L, C₁, C₂, C₃, C₄, C₅, C₆, C₇, C₈, C₉, C₁₀ and C₁₁ can be independently substituted by one or more substituents, or unsubstituted,
(ii) the pKa of above (i) mixture is on or more than 0.5, and on or less than 5.0, and
(iii) the polymerization solvent is selected from cyclic esters, cyclic amides, cyclic ketones or a mixture thereof.

28. The polymer manufacturing method according to claim 27,
wherein the weight average molecular weight (Mw) of the manufactured polymer satisfy below formula (2)″.
500 Da≤Mw≤10,000 Da formula (2)″

29. The polymer manufacturing method according to claim 27,
wherein the temperature of above (i) mixture is controlled between 80 to 160° C.

30. The polymer manufacturing method according to claim 27,
wherein the ratio of each (i) mixture components are molecule A is 1 part mass, molecule B is on or more than 0.5 to on or less than 2.0 parts mass,
a super acid catalyst is on or more than 2.0 to on or less than 5.0 parts mass, and solvent A is on or more than 1.0 to on or less than 4.0 parts mass.
